(19) United States
(12) Patent Application Publication
(10) Pub. No.: US 2011/0306157 A1
(43) Pub. Date: Dec. 15, 2011

(54) Opto-electrical Devices and Methods of Manufacturing the Same

(75) Inventors: Paul Wallace, Hertfordshire (GB); Simon Goddard, Cambrigeshire (GB)

(73) Assignee: CAMBRIDGE DISPLAY TECHNOLOGY LIMITED, Cambridgeshire (GB)

(21) Appl. No.: 13/056,336

(22) PCT Filed: Aug. 14, 2009
(86) PCT No.: PCT/GB09/01991

§ 371 Date: Mar. 29, 2011

(30) Foreign Application Priority Data
Aug. 15, 2008 (DE) 0814972.6

(51) Int. Cl. H01L 33/62; C09D 11/10; H01B 1/12

(52) U.S. Cl. 438/34; 252/500; 257/E33.062

(57) ABSTRACT

A composition for ink jet printing an opto-electrical device, comprising a charge injecting and/or transporting organic material and a solvent mixture, wherein the solvent mixture is present in an amount of about 30% v/v based on the volume of the composition and comprises a first co-solvent and a second co-solvent miscible with the first co-solvent; wherein the first co-solvent comprises ethylene glycol; and the second co-solvent comprises glycerol, wherein the ratio by volume of the first co-solvent to second co-solvent is approximately 1:2. The composition provides slower drying PEDOT ink formulations having improved film uniformity within pixels and across swathe joins which do not compromise other aspects of the ink's performance.

### FIELD OF INVENTION

This invention relates to compositions for ink jet printing opto-electrical devices, opto-electrical devices manufactured using these compositions, and methods of manufacturing these opto-electrical devices.

### BACKGROUND OF INVENTION

One class of opto-electrical devices is that using an organic material for light emission (or detection in the case of photovoltaic cells and the like). The basic structure of these devices is a light emissive organic layer, for instance a film of a poly (p-phenylenevinylene) (“PPV”) or polyfluorene, sandwiched between a cathode for injecting negative charge carriers (electrons) and an anode for injecting positive charge carriers (holes) into the organic layer. The electrons and holes combine in the organic layer generating photons. In WO90/13148 the organic light-emissive material is a polymer. In U.S. Pat. No. 4,539,507 the organic light-emissive material is of the class known as small molecule materials, such as (8-hydroxyquinoline) aluminium (“Alq3”). In a practical device one of the electrodes is transparent, to allow the photons to escape the device.

A typical organic light-emissive device (“OLED”) is fabricated on a glass or plastic substrate coated with a transparent anode such as indium-tin-oxide (“ITO”). A layer of a thin film of at least one electroluminescent organic material covers the first electrode. Finally, a cathode covers the layer of electroluminescent organic material. The cathode is typically a metal or alloy and may comprise a single layer, such as aluminium, or a plurality of layers such as calcium and aluminium.

In operation, holes are injected into the device through the anode and electrons are injected into the device through the cathode. The holes and electrons combine in the organic electroluminescent layer to form an exciton which then undergoes radiative decay to give light (in light detecting devices this process essentially runs in reverse).

These devices have great potential for displays. However, there are several significant problems. One is to make the device efficient, particularly as measured by its external power efficiency and its external quantum efficiency. Another is to optimise (e.g. to reduce) the voltage at which peak efficiency is obtained. Another is to stabilise the voltage characteristics of the device over time. Another is to increase the lifetime of the device.

To this end, numerous modifications have been made to the basic device structure described above in order to solve one or more of these problems.

One such modification is the provision of a layer of conductive polymer between the light-emissive organic layer and one of the electrodes. It has been found that the provision of such a conductive polymer layer can improve the turn-on voltage, the brightness of the device at low voltage, the efficiency, the lifetime and the stability of the device. In order to achieve these benefits these conductive polymer layers typically may have a sheet resistance less than 10⁶ Ohms/square, the conductivity being controllable by doping of the polymer layer. It may be advantageous in some device arrangements not to have too high a conductivity. For example, if a plurality of electrodes are provided in a device but only one continuous layer of conductive polymer extending over all the electrodes, then too high a conductivity can lead to lateral conduction (known as “cross-talk) and shorting between electrodes.

The conductive polymer layer may also be selected to have a suitable workfunction so as to aid in hole or electron injection and/or to block holes or electrons. There are thus two key electrical features: the overall conductivity of the conductive polymer composition; and the workfunction of the conductive polymer composition. The stability of the composition and reactivity with other components in a device will also be critical in providing an acceptable lifetime for a practical device. The processability of the composition will be critical for ease of manufacture.

Conductive polymer formulations are discussed in WO2006/070186. There is an ongoing need to optimise the organic formulations used in these devices both in the light emitting layer and the conductive polymer layer.

OLEDs can provide a particularly advantageous form of electro-optic display. They are bright, colourful, fast-switching, provide a wide viewing angle and are easy and cheap to fabricate on a variety of substrates. Organic (which here includes organometallic) LEDs may be fabricated using either polymers or small molecules in a range of colours (or in multi-coloured displays), depending upon the materials used. As previously described, a typical OLED device comprises two layers of organic material, one of which is a layer of light emitting material such as a light emitting polymer (LEP), oligomer or a light emitting low molecular weight material, and the other of which is a conductive polymer layer, for example a layer of a hole transporting material such as a polythiophene derivative or a polyaniline derivative.

Organic LEDs may be deposited on a substrate in a matrix of pixels to form a single or multi-colour pixellated display. A multicoloured display may be constructed using groups of red, green, and blue emitting pixels. So-called active matrix displays have a memory element, typically a storage capacitor and a transistor, associated with each pixel whilst passive matrix displays have no such memory element and instead are repetitively scanned to give the impression of a steady image.

FIG. 1 shows a vertical cross section through an example of an OLED device 100. In an active matrix display, part of the area of a pixel is occupied by associated drive circuitry (not shown in FIG. 1). The structure of the device is somewhat simplified for the purposes of illustration.

The OLED 100 comprises a substrate 102, typically 0.7 mm or 1.1 mm glass but optionally clear plastic, on which an anode layer 106 has been deposited. The anode layer typically comprises around 150 nm thickness of ITO (indium tin oxide), over which is provided a metal contact layer, typically around 500 nm of aluminium, sometimes referred to as anode metal. Glass substrates coated with ITO and contact metal may be purchased from Corning, USA. The contact metal (and optionally the ITO) is patterned as desired so that it does not obscure the display, by a conventional process of photolithography followed by etching.

A substantially transparent hole transport layer 108a is provided over the anode metal, followed by an electroluminescent layer 108b. Banks 112 may be formed on the substrate, for example from positive or negative photoresist material, to define wells 114 into which these active organic layers may be selectively deposited, for example by a droplet deposition or inkjet printing technique. The wells thus define light emitting areas or pixels of the display. As an alternative to wells, the photoresist may be patterned to form other types of openings into which the active organic layers may be selectively deposited. In particular, the photoresist may be patterned to form channels which, unlike wells, extend over a plurality of pixels and which may be closed or open at the channel ends, as disclosed in, for example, Carter et al, Proceedings of SPIE Vol. 4800, p. 34.

A cathode layer 110 is then applied by, say, physical vapour deposition. The cathode layer typically comprises a low work function metal such as calcium or barium covered with a thicker, capping layer of aluminium and optionally including an additional layer immediately adjacent the electroluminescent layer, such as a layer of lithium fluoride, for improved electron energy level matching. The cathode may be transparent. This is particularly preferred for active matrix devices wherein emission through the substrate is partially blocked by drive circuitry located underneath the emissive pixels. In the case of a transparent cathode device, it will be appreciated that the anode is not necessarily transparent. In the case of passive matrix displays, mutual electrical isolation of cathode lines may achieved through the use of cathode separators (element 302 of FIG. 3b). Typically a number of displays are fabricated on a single substrate and at the end of the fabrication process the substrate is scribed, and the displays separated. An encapsulant such as a glass sheet or a metal can is utilized to inhibit oxidation and moisture ingress.

Organic LEDs of this general type may be fabricated using a range of materials including polymers, dendrimers, and so-called small molecules, to emit over a range of wavelengths at varying drive voltages and efficiencies. Examples of polymer-based OLED materials are described in WO90/13148, WO95/06400 and WO99/48160; examples of dendrimer-based materials are described in WO 99/21935 and WO 02/067343; and examples of small molecule OLED materials are described in U.S. Pat. No. 4,539,507. The aforementioned polymers, dendrimers and small molecules emit light by radiative decay of singlet excitons (fluorescence). However, up to 75% of excitons are triplet excitons which normally undergo non-radiative decay. Electroluminescence by radiative decay of triplet excitons (phosphorescence) is disclosed in, for example, “Very high-efficiency green organic light-emitting devices based on electrophosphorescence” M. A. Baldo, S. Lamansky, P. E. Burrows, M. E. Thompson, and S. R. Forrest Applied Physics Letters, Vol. 75(1) pp. 4-6, Jul. 5, 1999″. In the case of a polymer-based OLED, layers 108 comprise a hole injection layer 108a and a light emitting polymer (LEP) electroluminescent layer 108b. The electroluminescent layer may comprise, for example, around 70 nm (dry) thickness of PPV (poly(p-phenylenevinylene)) and the hole injection layer, which helps match the hole energy levels of the anode layer and of the electroluminescent layer, may comprise, for example, around 50-200 nm, preferably around 150 nm (dry) thickness of PEDOT:PSS (polystyrene-sulphonate-doped polyethylene-dioxythiophene).

FIG. 2 shows a view from above (that is, not through the substrate) of a portion of a three-colour active matrix pixellated OLED display 200 after deposition of one of the active colour layers. The figure shows an array of banks 112 and wells 114 defining pixels of the display.

FIG. 3a shows a view from above of a substrate 300 for inkjet printing a passive matrix OLED display. FIG. 3b shows a cross-section through the substrate of FIG. 3a along line Y-Y′.

Referring to FIGS. 3a and 3b, the substrate is provided with a plurality of cathode undercut separators 302 to separate adjacent cathode lines (which will be deposited in regions 304). A plurality of wells 308 is defined by banks 310, constructed around the perimeter of each well 308 and leaving an anode layer 306 exposed at the base of the well. The edges or faces of the banks are tapered onto the surface of the substrate as shown, heretofore at an angle of between 10 and 40 degrees. The banks present a hydrophobic surface in order that they are not wetted by the solution of deposited organic material and thus assist in containing the deposited material within a well. This is achieved by treatment of a bank material such as polyimide with an O₂/CF₄ plasma as disclosed in EP 0989778. Alternatively, the plasma treatment step may be avoided by use of a fluorinated material such as a fluorinated polyimide as disclosed in WO 03/083960.

As previously mentioned, the bank and separator structures may be formed from resist material, for example using a positive (or negative) resist for the banks and a negative (or positive) resist for the separators; both these resists may be based upon polyimide and spin coated onto the substrate, or a fluorinated or fluorinated-like photoresist may be employed. In the example shown the cathode separators are around 5 μm in height and approximately 20 μm wide. Banks are generally between 20 μm and 100 μm in width and in the example shown have a 4 μm taper at each edge (so that the banks are around 1 μm in height). The pixels of FIG. 3a are approximately 300 μm square but, as described later, the size of a pixel can vary considerably, depending upon the intended application.

The deposition of material for organic light emitting diodes (OLEDs) using ink jet printing techniques is described in a number of documents including, for example: Y. Yang, “Review of Recent Progress on Polymer Electroluminescent Devices,” SPIE Photonics West: Optoelectronics '98, Conf. 3279, San Jose, January, 1998; EP 0 880 303; and “Ink-Jet Printing of Polymer Light-Emitting Devices”, Paul C. Duineveld, Margreet M. de Kok, Michael Buechel, Aad H. Sempel, Kees A. H. Mutsaers, Peter van de Weijer, Ivo G. J. Camps, Ton J. M. van den Biggelaar, Jan-Eric J. M. Rubingh and Eliav I. Haskal, Organic Light-Emitting Materials and Devices V, Zakya H. Kafafi, Editor, Proceedings of SPIE Vol. 4464 (2002). Ink jet techniques can be used to deposit materials for both small molecule and polymer LEDs.

A volatile solvent is generally employed to deposit a molecular electronic material, with 0.5% to 4% dissolved material. This can take anything between a few seconds and a few minutes to dry and results in a relatively thin film in comparison with the initial “ink” volume. Often multiple drops are deposited, preferably before drying begins, to provide sufficient thickness of dry material. Typical solvents which have been used include cyclohexylbenzene and alkylated benzenes, in particular toluene or xylene; others are described in WO 00/59267, WO 01/16251 and WO 02/18513; a solvent comprising a blend of these may also be employed. Precision ink jet printers such as machines from Litrex Corporation of California, USA are used; suitable print heads are available from Xaar of Cambridge, UK and Spectra, Inc. of NH, USA. Some particularly advantageous print strategies are described in WO2004/049466.

The feasibility of using ink jet printing to define hole conduction and electroluminescent layers in OLED display has been well demonstrated. The particular motivation for ink jet printing has been driven by the prospect of developing scalable and adaptable manufacturing processes, enabling large substrate sizes to be processed, without the requirement for expensive product specific tooling.

Recent years have seen an increasing activity in the development of ink jet printing for depositing electronic materials. In particular there have been demonstrations of ink jet printing of both hole conduction (HC) and electroluminescent (EL) layers of OLED devices by more than a dozen display manufacturers.

The key reasons for the interest in ink jet printing are scalability and adaptability. The former allows arbitrarily large sized substrates to be patterned and the latter should mean that there are negligible tooling costs associated with changing from one product to another since the image of dots printed on a substrate is defined by software. At first sight this would be similar to printing a graphic image—commercial print equipment is available that allow printing of arbitrary images on billboard sized substrates [Inca digital website: http://www.incadigital.com/]. However the significant difference between graphics printers and display panels is that the former use substrates that are porous or use inks that are UV curable resulting in very little effect of the drying environment on film formation. In comparison, the inks used in fabricating OLED displays are ink jet printed onto non-porous surfaces and the process of changing from a wet ink to dry film is dominated by the drying environment of the ink in the pixel. Since the printing process involves printing stripes (or swathes) of ink (corresponding to the ink jet head width) there is an inbuilt asymmetry in the drying environment. In addition OLED devices require the films to be uniform to nanometer tolerance. It follows that to achieve scalability and adaptability requires control of the film forming properties of the ink and a robustness of this process to changes in pixel dimensions.

In general terms, the behaviour of drying drops of HC and EL inks is explained by the coffee-ring effect first modelled by Deegan [R. D. Deegan, O. Bakajin, T. F. Dupont, G. Huber, S. R. Nagel, and T. A. Witten. Capillary flow as the cause of ring stains from dried liquid drops. Nature 389, 827 (1997)]. For the case of circular pixels the wet ink forms a section of a sphere, where the angle made by the drop surface with the substrate is the contact angle. When pinning occurs (which it invariably does for the inks and surfaces used in polymer OLED display manufacturing) the drying drop maintains its diameter and solute is carried to the edges of the drop forming a ring of material at the outer edges of the pixel. The amount of material carried to the edge depends on a number of factors—in particular how long the process of material transfer can occur before the drying drop gels and the uniformity of the drying environment.

Whilst ink jet printing has many advantages for the deposition of materials for opto-electrical devices, drawbacks are associated with the technique in view of the complexity of the drying process undergone by liquid drops. WO2006/123167 addresses a problem associated with asymmetric drying at the swathe join. Compositions for ink jet printing are provided which comprise an electroluminescent or charge transporting material and a high boiling point solvent. Glycerol-based PEDOT formulations were found to improve the film uniformity across swathe joins. These compositions comprise 30% glycerol and 69% water and 1% solids content of a 30 or 40:1 PSS:PEDOT formulation. Similar compositions were proposed using ethylene glycol instead of glycerol or 30% ethylene glycol with 2% glycerol.

It has been found that these formulations suffer from other drawbacks. Ink jet printing an array of pixels using a composition with a high concentration of glycerol tends to result in a problem of leakage path which leads to poor efficiency at low luminance. For reasons which are not entirely clear, current leakage occurs through the device. This is exacerbated when the PEDOT:PSS ratio is reduced to increase the conductivity of the composition. On the other hand, substituting for glycerol other polyols such as ethylene glycol gives rise to problems in the surface uniformity of the deposited layers.

A need therefore exists for improved compositions for ink jet printing opto-electrical devices which do not suffer from the drawbacks of the prior art.

### SUMMARY OF THE INVENTION

According to a first aspect, the present invention provides a composition for ink jet printing an opto-electrical device, which composition comprises a charge injecting and/or transporting organic material and a solvent mixture, wherein the solvent mixture is present in an amount of at least 20% v/v based on the volume of the composition and comprises a first co-solvent and a second co-solvent miscible with the first co-solvent; wherein the first cosolvent comprises a mono- or di-hydric alcohol or an ether or ester thereof; and the second co-solvent is present in an amount of co-solvent at least 5% v/v based on the volume of the composition and comprises a C₃-C₅ trihydric or tetrhydric alcohol or an ether or ester thereof.

A charge injecting layer may be deposited as a composition comprising the charge transporting organic material in a composition according to the present invention. Preferably, the organic material comprises a polymer and most preferably the organic material comprises PEDOT with a suitable polyanion, for example PSS. Another example is polythienothiophene with a polyanion.

Embodiments of the present invention relate to new PEDOT ink formulations for improved film uniformity within pixels and across swathe joins. Slower drying inks have been formulated which do not compromise other aspects of the ink's performance.

The present applicant has found that the problem of film non-uniformity in PEDOT is very important to device performance, especially EL device performance. The device performance may not be directly affected significantly by the thickness of the PEDOT film. However, the uniformity of the PEDOT film affects the uniformity of the overlying electroluminescent layer. The EL layer is very sensitive to changes in thickness. Accordingly, the present applicant has found that it is paramount that uniform films of PEDOT profiles are achieved in order to achieve uniform EL profiles.

The quantity of counterion present in a PEDOT:counterion composition is at least sufficient to balance the charge on PEDOT, and the PEDOT:counterion ratio may be in the range 1:2.5 to 1:18, more preferably up to 1:6 to 1:20. Preferably, the counterion is a polymeric acid such as a polysulfonic acid (for example PSS or Nafion) or poly acrylic acid. Most preferably, the counterion is PSS.

The lateral resistivity of the film is usually 10 to 5000 and preferably no more than about 1000 ohm.cm.

The solvent mixture may dissolve the organic material, or the solvent and organic material may together form a dispersion. For example, an aqueous composition of PEDOT/PSS is in the form of a dispersion. Preferably, the solvent mixture further comprises water.

It has surprisingly been found that by adjusting the proportion of the first and second co-solvents, compositions for ink jet printing may be provided which suffer neither from the leakage path problem nor from the problem of surface roughness experienced in the prior art. Without wishing to be bound by theory, it is believed that the trihydric alcohol or ether or ester thereof enhances surface smoothness of a deposited ink drop whereas the presence of the mono- or di-hydric alcohol abrogates the effect of the trihydric alcohol or ether or ester thereof on the leakage path problem. This is achieved without substantial abrogation of the surface smoothing effect.

It is preferred that the solvent mixture is present in an amount of at least 20% by volume of the composition. Very high percentages of solvent mixture may give rise to a composition which is too viscous for ink jet printing. Viscosity above 20 mPas is highly undesirable and it is preferred that the viscosity is no more than 12 mPas, preferably no more than 10 mPas. The solvent mixture is preferably present in the composition in an amount of from 20% to 50% by volume of the composition, preferably no more than 30% by volume of the composition. A particular useful amount is about 30% by volume of the composition.

Conveniently, solvent mixture includes water and the first and second co-solvents have a higher boiling point than water. This allows the composition to have a useful viscosity for ink jet printing and provides an overall solvent composition suitable for dissolving or dispersing solid components. On application of a drop of the composition to a well or other target substrate, the aqueous component will evaporate first.

The first co-solvent is preferably present in the solvent mixture in a ratio by volume to the second co-solvent of from 1:1 to 1:5. In this way, where 30% by volume of solvent mixture is present in the composition, this gives rise to a range of 5 to 15% of the first co-solvent expressed by volume of the overall composition. It is particularly preferred that the ratio by volume of the first co-solvent to the second co-solvent is approximately 1:2. Thus, in a particularly preferred arrangement, there may be 10% of the first co-solvent and 20% of the second co-solvent, by volume of the composition. In this way, a good balance between the surface smoothness and prevention of the leakage path problem is achieved.

The first co-solvent comprises a mono- or di-hydric alcohol or an ether or ester thereof. A preferred first co-solvent is ethylene glycol.

The second co-solvent may comprise a C₃-C₅ trihydric alcohol or an ether or ester thereof. Glycerol is the preferred second co-solvent.

The solubility, processability and functional properties of the organic material may be very sensitive to changes in solvent. Accordingly, it is advantageous to retain a portion of solvent in which the organic material is stable. As such, the solvent will typically be the usual solvent used for the organic material for achieving good solubility, processability and conduction characteristics. Suitable solvents for non-polar organic materials include mono- or poly-alkylated benzenes, for example xylene. Water may be a suitable solvent for some organic materials, particularly conductive organic materials such a doped PEDOT.

Preferably, the boiling point of the solvent mixture is between 110 and 400 degrees centigrade.

For small pixels a higher solid content is generally used. For larger pixels a lower solid content is used. For larger pixels, the concentration of the composition is reduced to get good film forming properties. Typical solids content ranges from 0.1 to 2 wt %, preferably 0.5 to 0.9 wt %, based on the volume of the composition.

If the solvent is very viscous then it can become difficult to ink jet print the composition. If the viscosity of the composition becomes too high then it will not be suitable for ink jet printing without heating the print head. Embodiments of the present invention are preferably of a viscosity such that heating of the print head is not required in order to ink jet print the compositions.

Furthermore, if the contact angle between the solvent and the base of the well is too high, then the base of the well may not be sufficiently wetted. Conversely, if the contact angle between the solvent and the banks is too low, then the banks may not contain the composition leading to flooding of the wells.

Thus, selecting an arbitrary high boiling point solvent can alter the wetting characteristics of the composition. For example, if the contact angle between the composition and the base of the well is too large then on drying the film has thin edges resulting in non-uniform emission. Alternatively, if the contact angle between the composition and the bank is too small then the well will flood. With such an arrangement, on drying, conductive/semi-conductive organic material will be deposited over the bank structure leading to problems of shorting.

Preferably, the composition should have a contact angle with the base of the well such that it wets the base of the well but does not flood out of the well. With this arrangement, on drying no coffee ring effect occurs which would result in a thickening of the edges. A more uniform (i.e. smoother) film therefore results producing a more uniform emission in the finished device.

If the contact angle between the electroluminescent material and the conductive material is too high then the conductive material will not be sufficiently wetted by the electroluminescent material.

One solution to the problem of flooding is to select a high boiling point solvent which has a sufficient contact angle such that it is adequately contained in the wells. Conversely, one solution to the problem of insufficient wetting of the base of the well is to select a high boiling point solvent which provides a composition that does not have a high contact angle with the material of the base of the well and does have a high contact angle with the banks.

The problem of insufficient wetting or flooding can be controlled by the addition of a suitable additive to modify the contact angle of the formulation such that the well is sufficiently wetted without flooding. The provision of such a additive can also produce flatter film morphologies.

A surfactant may be added to the composition to increase the ability of the composition to wet the well. Suitable surfactants include alcohol ethers such as 2-butoxyethanol.

In the case where the composition of the invention is inkjet printed, it preferably has a surface tension of at least 35 mN/m to avoid leakage of the composition from the inkjet print head.

According to another aspect of the present invention there is provided use of a composition, as described herein, for printing, preferably by ink jetting a layer in the manufacture of an opto-electronic device.

According to another aspect of the present invention there is provided an opto-electrical device formed using the compositions described herein.

According to yet another aspect of the present invention there is provided a process for the manufacture of an organic light-emissive display comprising: providing a substrate comprising a first electrode layer and a bank structure defining a plurality of openings; depositing a conductive organic layer over the first electrode; depositing an organic light-emissive layer over the conductive organic layer; and depositing a second electrode over the organic light-emissive layer, wherein the conductive organic layer is deposited by ink jet printing a composition as described herein into the plurality of openings.

According to yet another aspect of the present invention there is provided a method of forming a film of charge injecting and/or transporting organic material comprising the steps of depositing a formulation comprising a charge injecting and/or transporting organic material, a solvent, and first and second co-solvents; and evaporating the solvents, wherein the root mean square roughness of the films is less than 1 nm.

Each solvent and co-solvent is preferably as defined herein. The charge injecting and/or transporting organic material is preferably as defined herein. The roughness of the surface of the films may be measured using a Zygo white light interferometer.

### BRIEF SUMMARY OF THE DRAWINGS

Embodiments of the present invention will now be described, by way of example only, with reference to the accompanying drawings in which:

FIG. 1 shows a vertical cross section through an example of an OLED device;

FIG. 2 shows a view from above of a portion of a three colour pixelated OLED display; and

FIGS. 3a and 3b show a view from above and a cross-sectional view respectively of a passive matrix OLED display;

FIG. 4 shows a graph of current density against voltage on which is compared devices according to the present invention with conventional devices;

FIG. 5 shows a graph of efficiency against voltage on which is compared devices according to the present invention with conventional devices; and

FIG. 6 shows a graph of efficiency against luminance on which is compared devices according to the present invention with conventional devices.

### DETAILED DESCRIPTION OF PREFERRED EMBODIMENTS

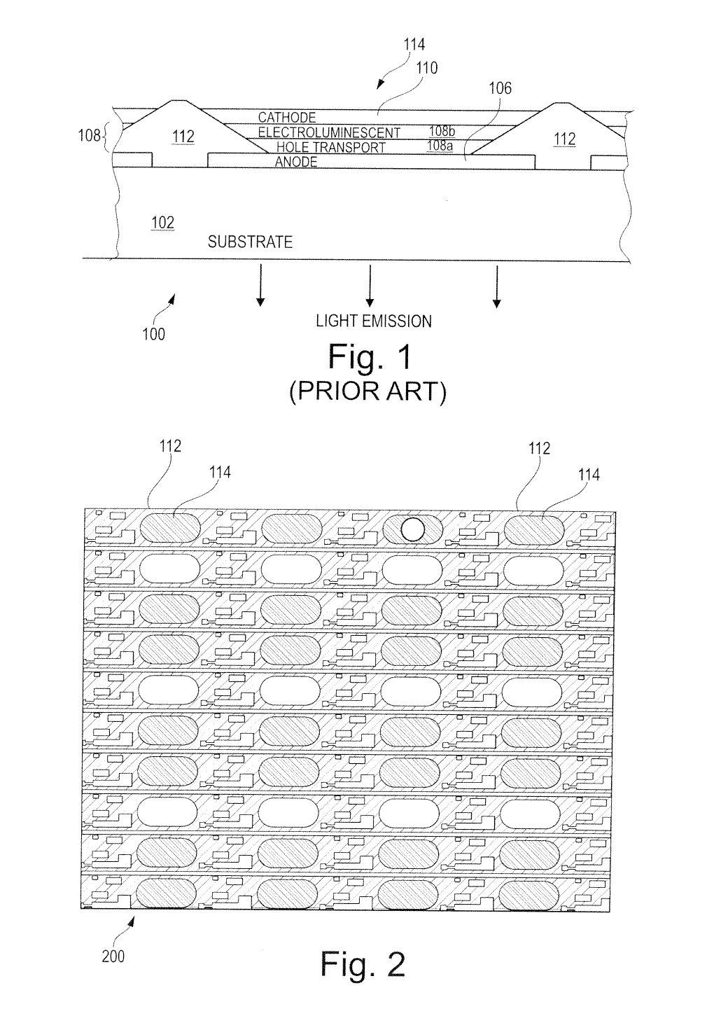

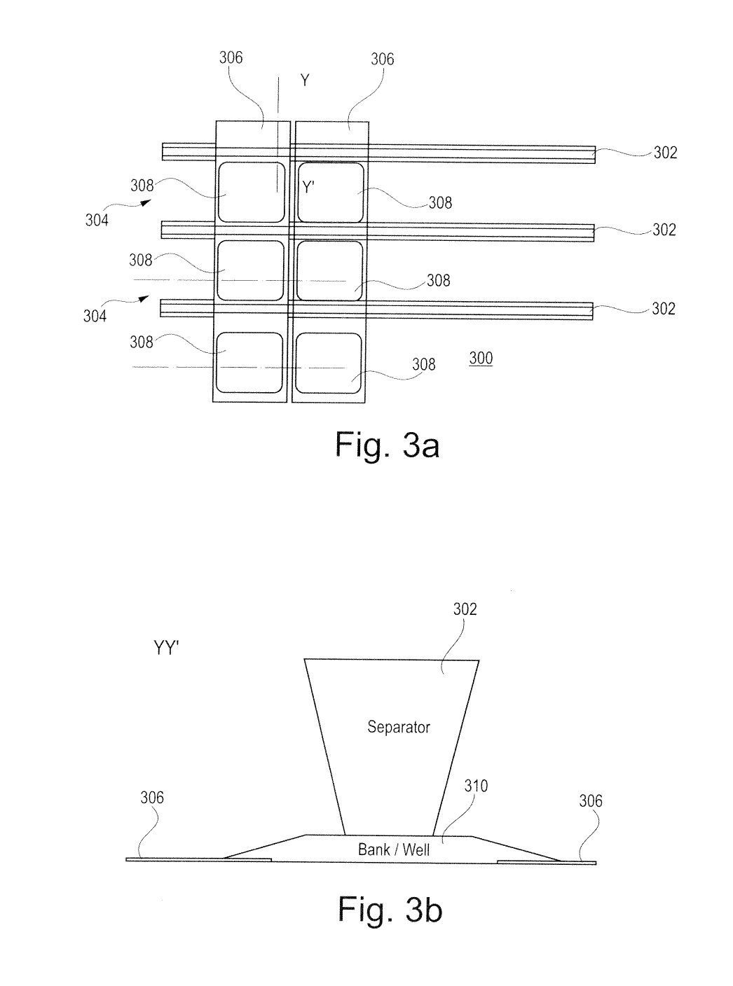

The general device architecture is illustrated in FIG. 1 and has been described above.

The device is preferably encapsulated with an encapsulant (not shown) to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

Suitable polymers for charge transport and emission may comprise a first repeat unit selected from arylene repeat units, in particular: 1,4-phenylene repeat units as disclosed in J. Appl. Phys. 1996, 79, 934; fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

Particularly preferred polymers comprise optionally substituted, 2,7-linked fluorenes, most preferably first repeat units of formula:

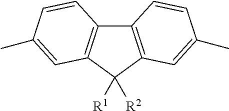

wherein R¹ and R² are independently selected from hydrogen or optionally substituted alkyl, alkoxy, aryl, arylalkyl, heteroaryl and heteroarylalkyl. More preferably, at least one of R¹ and R² comprises an optionally substituted C₄-C₂₀ alkyl or aryl group.

A polymer comprising the first repeat unit may provide one or more of the functions of hole transport, electron transport and emission depending on which layer of the device it is used in and the nature of co-repeat units.

In particular:

a homopolymer of the first repeat unit, such as a homopolymer of 9,9-dialkylfluoren-2,7-diyl, may be utilised to provide electron transport;

a copolymer comprising a first repeat unit and a triarylamine repeat unit utilised to provide hole transport and/or emission; or

a copolymer comprising a first repeat unit and heteoarylene repeat unit may be utilised for charge transport or emission.

Electroluminescent copolymers may comprise an electroluminescent region and at least one of a hole transporting region and an electron transporting region as disclosed in, for example, WO 00/55927 and U.S. Pat. No. 6,353,083. If only one of a hole transporting region and electron transporting region is provided then the electroluminescent region may also provide the other of hole transport and electron transport functionality.

The different regions within such a polymer may be provided along the polymer backbone, as per U.S. Pat. No. 6,353,083, or as groups pendant from the polymer backbone as per WO 01/62869.

A single polymer or a plurality of polymers may be deposited from solution to form layer 5. Suitable solvents for polyarylenes, in particular polyfluorenes, include mono- or poly-alkylbenzenes such as toluene and xylene. Particularly preferred solution deposition techniques are spin-coating and inkjet printing.

In some cases, distinct layers of the device may be formed by different methods, for example a hole injection and/or transport layer may be formed by spin-coating and an emissive layer may be deposited by inkjet printing.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

The emissive species may be metal complexes. The metal complexes may comprise optionally substituted complexes of formula (22):

ML¹_{q}L²ᵣL³ₛ (22)

wherein M is a metal; each of L¹, L² and L³ is a coordinating group; q is an integer; r and s are each independently 0 or an integer; and the sum of (a·q)+(b·r)+(c·s) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet states (phosphorescence). Suitable heavy metals M include:

lanthanide metals such as cerium, samarium, europium, terbium, dysprosium, thulium, erbium and neodymium; and

d-block metals, in particular those in rows 2 and 3 i.e. elements 39 to 48 and 72 to 80, in particular ruthenium, rhodium, palladium, rhenium, osmium, iridium, platinum and gold.

Suitable coordinating groups for the f-block metals include oxygen or nitrogen donor systems such as carboxylic acids, 1,3-diketonates, hydroxy carboxylic acids, Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal. The sharp emission is generally narrow, resulting in a pure colour emission useful for display applications.

The d-block metals form organometallic complexes with carbon or nitrogen donors such as porphyrin or bidentate ligands of formula (VI):

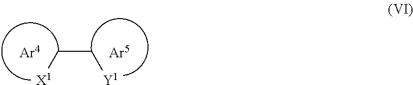

wherein Ar⁴ and Ar⁵ may be the same or different and are independently selected from optionally substituted aryl or heteroaryl; X¹ and Y¹ may be the same or different and are independently selected from carbon or nitrogen; and Ar⁴ and Ar⁵ may be fused together. Ligands wherein X¹ is carbon and Y¹ is nitrogen are particularly preferred.

Examples of bidentate ligands are illustrated below:

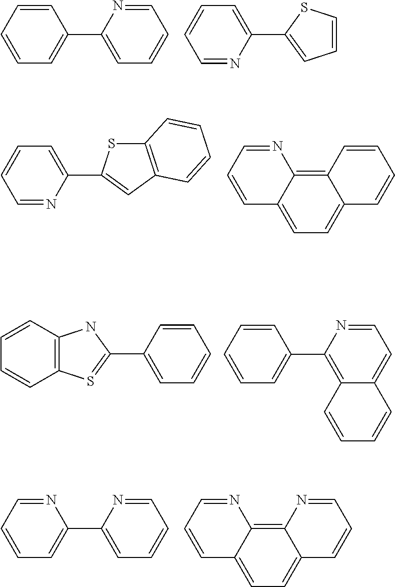

Each of Ar⁴ and Ar⁵ may carry one or more substituents. Particularly preferred substituents include fluorine or trifluoromethyl which may be used to blue-shift the emission of the complex as disclosed in WO 02/45466, WO 02/44189, US 2002-117662 and US 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in WO 02/68435 and EP 1245659; and dendrons which may be used to obtain or enhance solution processability of the metal complex as disclosed in WO 02/66552.

Other ligands suitable for use with d-block elements include diketonates, in particular acetylacetonate (acac); triarylphosphines and pyridine, each of which may be substituted.

Main group metal complexes show ligand based, or charge transfer emission. For these complexes, the emission colour is determined by the choice of ligand as well as the metal.

The host material and metal complex may be combined in the form of a physical blend. Alternatively, the metal complex may be chemically bound to the host material. In the case of a polymeric host, the metal complex may be chemically bound as a substituent attached to the polymer backbone, incorporated as a repeat unit in the polymer backbone or provided as an end-group of the polymer as disclosed in, for example, EP 1245659, WO 02/31896, WO 03/18653 and WO 03/22908.

### Composition Formation Procedure

The composition according to the invention may be prepared by simply blending the first and second co-solvents, optionally with the charge transporting and/or injecting material, optionally with further additives such as a surfactant.

In the case of doped PEDOT, the alcohol ether additive may be blended with a commercially available aqueous dispersion of doped PEDOT, for example PEDOT:PSS sold under the name Baytron P® by H C Starck of Leverkusen, Germany. Further solvents and/or additives may also be added in order to optimise the properties of the dispersion such as its jettability, drying characteristics and resistivity, and/or in order to improve the performance of the end device. Exemplary further additives include polymeric acids, for example excess PSS.

An exemplary composition according to the present invention comprises commercially available Baytron P VP AI4083.

### Device Manufacturing Procedure

The procedure follows the steps outlined below:

1) Depositing a PEDOT/PSS composition according to the present invention onto indium tin oxide supported on a glass substrate (available from Applied Films, Colorado, USA).

2) Depositing from solution a layer of hole transporting polymer.

3) Heating the layer of hole transport material in an inert (nitrogen) environment.

4) Optionally spin-rinsing the substrate in xylene to remove any remaining soluble hole transport material.

5) Depositing from solution an organic light-emissive material.

6) Depositing a metal compound/conductive material bi-layer cathode over the organic light-emissive material and encapsulating the device using an airtight metal enclosure available from Saes Getters SpA.

### Full Colour Display Manufacturing Procedure

A full colour display can be formed according to the process described in EP 0880303 by forming wells for red, green and blue subpixels using standard lithographical techniques; inkjet printing PEDOT/PSS into each subpixel well; inkjet printing hole transport material; and inkjet printing red, green and blue electroluminescent materials into wells for red, green and blue subpixels respectively.

As an alternative to printing into wells, a display may also be formed by printing into channels.

The following examples describe spin-coating and inkjet printing of compositions according to the present invention. However, it will be appreciated that the compositions may be deposited by other deposition techniques including flexographic printing such as roll-printing and gravure printing; screen printing; spray coating; slot coating; nozzle coating; and dip-coating. The skilled person will be aware of the optimal physical properties of the composition, such as viscosity, that should be adjusted for each of the above deposition techniques.

### Examples

### 1. Formulations

Details of the formulations used in the present examples are set out in Table 1. In each case the PEDOT:PSS composition is supplied as Baytron PAI4083 to which is added extra PSS as shown in the PEDOT:PSS ratio in the Table. Formulation 1 is according to the invention, as is Formulation 4. Formulation 4 is a spin coated equivalent of Formulation 1 made for the purpose of testing current leakage (see below). The remaining examples are Comparative Examples.

TABLE 1

| | Solids | PEDT- | | | |
|---|---|---|---|---|---|
| Formulation | content | PSS | | Ethylene | |
| number | (% wt) | ratio | Glycerol | glycol | Butoxyethanol |
| 1 | 0.7 | 1-18 | 20 | 10 | 0 |
| 2 | 0.45 | 1-6 | 30 | 0 | 0 |
| 3 | 0.6 | 1-6 | 30 | 0 | 1 |
| 4 | 1.5 | 1-18 | 20 | 10 | 0.5 |
| 5 | 0.9 | 1-6 | 30 | 0 | 0.5 |
| 6 | 0.9 | 1-6 | 30 | 0 | 1 |

### 2. Current Leakage

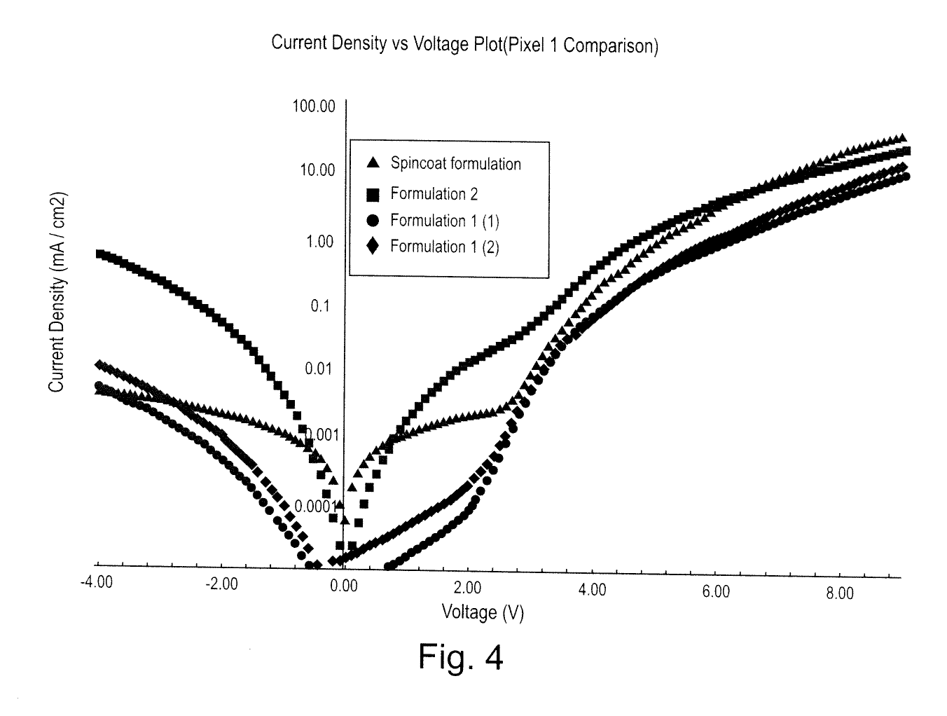

FIG. 4 shows a graph of current density against voltage for four different formulations. It will be apparent from the results that Formulation 1 according to the invention has much lower current leakage, particularly at low voltage. The current density scale is a log scale demonstrating leakage currents two orders of magnitude lower for Formulation 1 as compared to Formulation 2. Formulation 2 is made from a composition comprising 30% glycerol and no ethylene glycol whereas Formulation 1 has 20% glycerol and 10% ethylene glycol. Notably, it is not the film resistivity which is responsible for the differences in leakage path because Formulation 1 has almost the same lateral film resistivity as Formulation 2.

### 3. Device Efficiency

Organic electroluminescent devices were manufactured according to the previously described process.

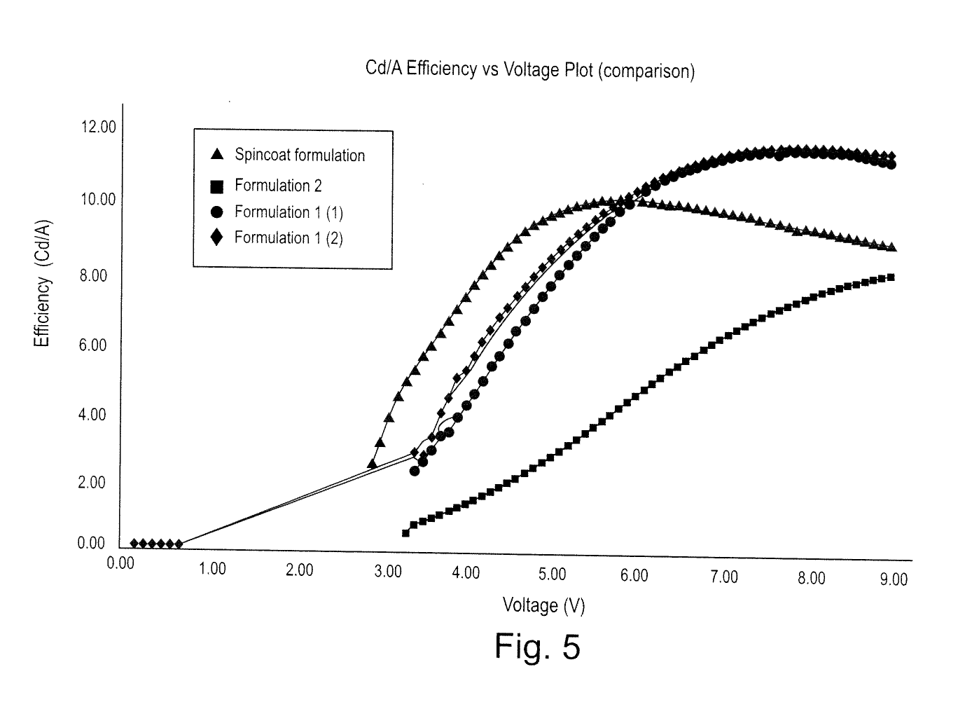

FIG. 5 shows a graph of efficiency against voltage for devices incorporating a hole transport layer as described above for FIG. 4. It will be apparent that as the voltage is increased the device efficiency measured in candelas per ampere also increases. This efficiency continues to increase for the devices according to the invention. In the Comparative Examples, the efficiency is reduced or decreases as the voltage increases.

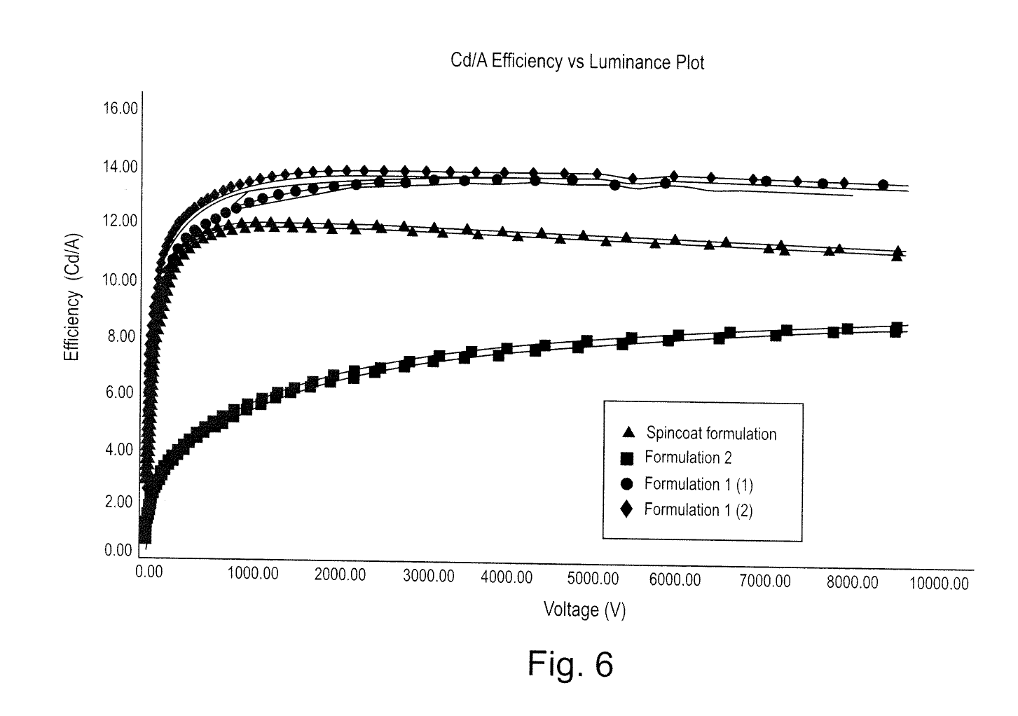

FIG. 6 shows the efficiency plotted against the luminance. The efficiency values are higher for devices according to the invention as compared with the Comparative Examples.

Taken together these results show that devices according to the invention are superior to conventional devices in terms of leakage current and efficiency.

### 4. Surface Roughness

The roughness of the surface of the ink jet printed layers in the pixels may be measured using a Zygo white light interferometer. It is found that if ethylene glycol is used as the only solvent then the PEDOT:PSS films produced a very domed and rough. However, if a blend of ethylene glycol with glycerol is used according to the present invention, the film profile is controlled and film roughness reduced.

In conclusion, an embodiment of the present invention provides compositions for ink jet printing an opto-electrical device, comprising a charge injecting and/or transporting organic material and a solvent mixture, wherein the solvent mixture is present in an amount of about 30% v/v based on the volume of the composition and comprises a first co-solvent and a second co-solvent miscible with the first co-solvent; wherein the first co-solvent comprises ethylene glycol; and the second co-solvent comprises glycerol, wherein the ratio by volume of the first co-solvent to second co-solvent is approximately 1:2, preferably between 1:1 and 1:3. The composition provides slower drying PEDOT ink formulations having improved film uniformity within pixels and across swathe joins which do not compromise other aspects of the ink's performance.

1. A composition for ink jet printing an opto-electrical device, the composition comprising a charge injecting and/or transporting organic material and a solvent mixture, wherein:
the solvent mixture is present in an amount of at least 20% v/v based on the volume of the composition and comprises a first co-solvent and a second co-solvent miscible with the first co-solvent;
the first co-solvent comprises a mono- or di-hydric alcohol or an ether or ester thereof; and
the second co-solvent is present in an amount of co-solvent at least 5% v/v based on the volume of the composition and comprises a C₃-C₅ trihydric or tetrhydric alcohol or an ether or ester thereof.

2. A composition according to claim 1, wherein the first and second co-solvents are present in an amount of from 20% to 50% by volume of the composition.

3. A composition according to claim 2, wherein the first and second co-solvents are present in an amount of about 30% by volume of the composition.

4. A composition according to claim 1, wherein the ratio by volume of the first co-solvent to second co-solvent is from 2:1 to 1:5.

5. A composition according to claim 4, wherein the ratio by volume of the first co-solvent to second co-solvent is approximately 1:2.

6. A composition according to claim 1, wherein the first co-solvent comprises ethylene glycol.

7. A composition according to claim 1, wherein the second co-solvent comprises glycerol.

8. A composition according to claim 1, in which the solvent mixture further comprises water, wherein the first and second co-solvents each have a higher boiling point than water.

9. A composition according to claim 1, wherein the charge transporting and/or injecting organic material is polymeric.

10. A composition according to claim 1, wherein the charge transporting and/or injecting organic material comprises a hole injecting material.

11. A composition according to claim 10, wherein the hole injecting material comprises doped poly(ethylene dioxythiophene) (PEDOT).

12. A composition according to claim 1, which further comprises a surfactant.

13. A composition according to claim 12, wherein the surfactant is an alcohol ether.

14. (canceled)

15. (canceled)

16. A process for the manufacture of an organic light-emissive display comprising:
providing a substrate comprising a first electrode layer and a bank structure defining a plurality of openings;
depositing a conductive organic layer over the first electrode;
depositing an organic light-emissive layer over the conductive organic layer; and
depositing a second electrode over the organic light-emissive layer, wherein the conductive organic layer is deposited by ink jet printing a composition according to claim 1 into the plurality of openings.

17. A method of forming a film of charge injecting and/or transporting organic material comprising the steps of depositing a formulation comprising a charge injecting and/or transporting organic material, a solvent, and first and second co-solvents; and evaporating the solvents, wherein the root mean square roughness of the films is less than 1 nm.
